(19) United States
(12) Patent Application Publication
(10) Pub. No.: US 2021/0159054 A1
(43) Pub. Date: May 27, 2021

(54) GAS SUPPLY SYSTEM, PLASMA PROCESSING APPARATUS, AND CONTROL METHOD OF GAS SUPPLY SYSTEM

(71) Applicant: TOKYO ELECTRON LIMITED, Tokyo (JP)

(72) Inventors: Hwajun JUNG, Miyagi (JP); Yuji KITAMURA, Miyagi (JP)

(73) Assignee: TOKYO ELECTRON LIMITED, Tokyo (JP)

(21) Appl. No.: 17/094,870

(22) Filed: Nov. 11, 2020

(30) Foreign Application Priority Data
Nov. 21, 2019 (JP) 2019-210537

(51) Int. Cl. H01J 37/32

(52) U.S. Cl. CPC H01J 37/32449; H01J 2237/006; H01J 37/32082

(57) ABSTRACT

A gas supply system is connected between at least one gas source and a chamber having a first and a second gas inlet. The gas supply system includes a flow adjusting unit including flow adjusting lines, each including a pair of a first line and a second line. The first line connects the at least one gas source and the first gas inlet and has a first valve and a first orifice, the second line connects the at least one gas source and the second gas inlet and has a second valve and a second orifice, and the first orifice and the second orifice in each of the flow adjusting lines have the same size. The gas supply system further includes at least one control unit configured to control an opening/closing of the first valve and an opening/closing of the second valve in each of the flow adjusting lines.

### CROSS-REFERENCE TO RELATED APPLICATIONS

This application claims priority to Japanese Patent Application No. 2019-210537, filed on Nov. 21, 2019, the entire contents of which are incorporated herein by reference.

### TECHNICAL FIELD

The present disclosure relates to a gas supply system, a plasma processing apparatus, and a control method of the gas supply system.

### BACKGROUND

There is known a plasma processing apparatus for performing desired processing on a substrate placed on a substrate support in a chamber by supplying a processing gas into the chamber from a plurality of gas inlet units.

U.S. Pat. No. 8,772,171 discloses a flow control unit that divides the flow of a gas introduced in a gas line into two separate outlet flows of the gas.

### SUMMARY

The present disclosure provides a gas supply system and a plasma processing apparatus configured to distribute a gas with high responsiveness, and a control method of the gas supply system.

In accordance with an aspect of the present disclosure, there is provided a gas supply system connected between at least one gas source and a chamber having a first gas inlet and a second gas inlet. The gas supply system includes a flow adjusting unit including a plurality of flow adjusting lines, each including a pair of a first line and a second line. The first line connects the at least one gas source and the first gas inlet and has a first valve and a first orifice; the second line connects the at least one gas source and the second gas inlet and has a second valve and a second orifice; and the first orifice and the second orifice in each of the flow adjusting lines have the same size. The gas supply system further includes at least one control unit configured to control an opening/closing of the first valve and an opening/closing of the second valve in each of the flow adjusting lines.

### BRIEF DESCRIPTION OF THE DRAWINGS

The objects and features of the present disclosure will become apparent from the following description of embodiments, given in conjunction with the accompanying drawings, in which:

FIG. 1 is a schematic cross-sectional view of an example of a plasma processing apparatus;

FIG. 2 shows an example of a configuration of a gas splitter;

FIGS. 3A and 3B show examples of a table stored in a control unit;

FIG. 4 is a flowchart for explaining an example of a process of controlling a flow ratio by the control unit;

FIG. 5 shows an example of a combination of orifice sizes;

FIG. 6 shows an example of a graph showing a simulation result;

FIG. 7 is a schematic cross-sectional view showing another example of the plasma processing apparatus; and

FIG. 8 shows a schematic configuration of another example of the gas splitter.

### DETAILED DESCRIPTION

Hereinafter, embodiments will be described in detail with reference to the accompanying drawings. Like reference numerals will be given to like parts throughout the drawings, and redundant description thereof may be omitted.

(Configuration of the Plasma Processing Apparatus 10)

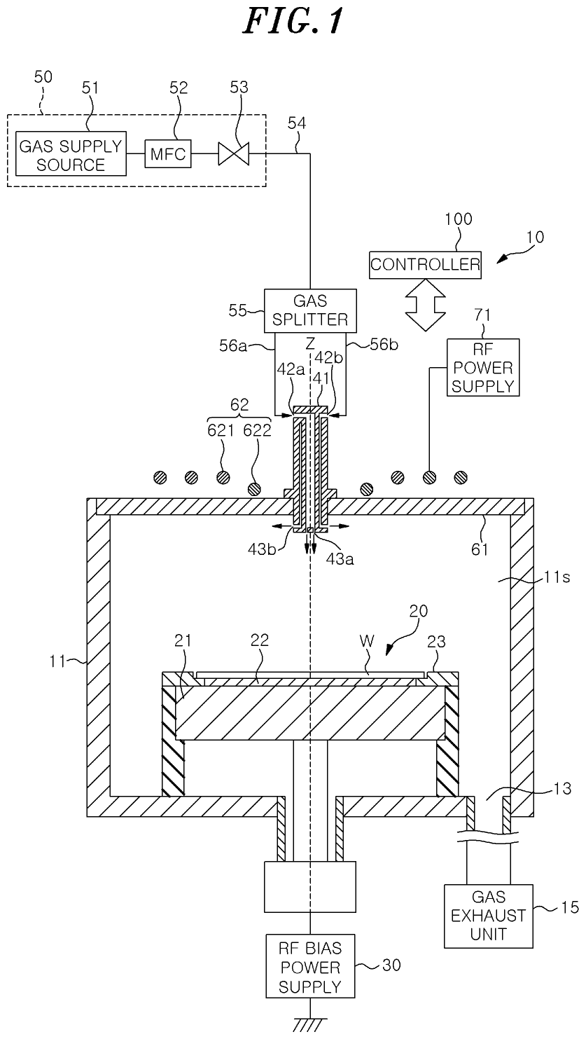

FIG. 1 is a schematic cross-sectional view of an example of a plasma processing apparatus 10. The plasma processing apparatus 10 includes a chamber 11 having a plasma processing space 11s.

The plasma processing apparatus 10 includes a substrate support 20. The substrate support 20 is disposed in the plasma processing space 11s and is configured to support a substrate W (e.g., wafer). The substrate support 20 includes a lower electrode 21 functioning as a bias electrode. The central axis of the substrate support 20 is defined as the Z-axis.

A radio frequency (RF) bias power supply 30 is connected to the lower electrode 21. The RF bias power supply 30 is configured to supply a RF bias power having, for example, a frequency of 13 MHz to the lower electrode 21. The frequency and the power of the RF bias power are controlled by a controller 100 to be described later.

The substrate support 20 includes an electrostatic chuck 22 for attracting and holding the wafer W by an electrostatic attractive force. The substrate support 20 includes an edge ring 23 disposed on an upper surface of a peripheral portion of the lower electrode 21 to surround the wafer W.

Although it is not illustrated, in one embodiment, the substrate support 20 may include a temperature control module configured to adjust at least one of the electrostatic chuck 22 and the substrate W to a target temperature. The temperature control module may include a heater, a flow channel, or a combination thereof. A temperature control fluid such as a coolant or a heat transfer gas flows through the flow channel. The temperature control module is controlled by the controller 100 to be described later.

A gas exhaust port 13 is formed at a bottom surface of the chamber 11 and is connected to a gas exhaust unit 15.

The gas exhaust unit 15 is controlled by the controller 100 to be described later.

The plasma processing apparatus 10 includes a dielectric window 61 disposed at an upper portion of the chamber 11. The plasma processing apparatus 10 further includes a gas injection unit (center gas injector) 41 configured to introduce a processing gas into the plasma processing space 11s. The gas injection unit 41 has a substantially cylindrical outer shape and is disposed at an opening formed at the center of the dielectric window 61.

The gas injection unit 41 includes inlet ports 42a and 42b for introducing the processing gas into the gas injection unit 41. The inlet ports 42a and 42b are disposed at an upper portion of the gas injection unit 41, for example. A lower portion of the gas injection unit 41 projects downward beyond a bottom surface of the dielectric window 61. Therefore, the lower portion of the gas injection unit 41 is exposed to the plasma processing space 11s. The gas injection unit 41 includes an injection port 43a for injecting the processing gas downward along the Z-axis and an injection port 43b for injecting the processing gas laterally, i.e., in a direction away from the Z-axis. The injection ports 43a and 43b are formed at the lower portion of the gas injection unit 41 exposed to the plasma processing space 11s. The inlet port 42a is an example of a first gas inlet, and the inlet port 42b is an example of a second gas inlet. The injection port 43a is an example of a first injection port, and the injection port 43b is an example of a second injection port.

The plasma processing apparatus 10 includes a gas supply unit 50 and a gas splitter (gas supply system) 55.

The inlet ports 42a and 42b are connected to the gas supply unit 50 through the gas splitter 55.

The gas supply unit 50 includes a gas supply source 51, a mass flow controller (MFC) 52, and a valve 53. The gas supply source 51 is configured to supply the processing gas to the gas splitter 55 through a gas supply line 54. The MFC 52 and the valve 53 are disposed on the gas supply line 54. The MFC 52 is configured to control a flow rate of the processing gas supplied from the gas supply source 51. In other words, the MFC 52 controls a total flow of the processing gas supplied from the gas supply source 51 to the plasma processing space 11s in the chamber 11. The valve 53 is configured to control the supply and the shut-off of the supply of the processing gas. The MFC 52 and the valve 53 are separately controlled by the controller 100 to be described later.

The gas splitter 55 is configured to supply the processing gas supplied through the gas supply line 54 to the gas supply lines 56a and 56b at a flow ratio instructed by the controller 100 to be described later. The gas supply line 56a is connected to the inlet port 42a. The gas supply line 56b is connected to the inlet port 42b. The gas splitter 55 is controlled by the controller 100 to be described later.

As described above, the plasma processing apparatus 10 controls the total flow of the processing gas supplied into the chamber 11 in the MFC 52 to control the flow ratio of two gas lines in the gas splitter 55. Accordingly, it is possible to perform various flow control of the processing gas supplied to the plasma processing space 11s in the chamber 11.

In the present embodiment, the gas supply source 51 supplies as a processing gas an etching gas such as CF₄ gas or chlorine gas into the chamber 11. The gas supply unit 50 includes at least one gas supply source 51, or may include multiple gas supply sources 51. When the gas supply unit 50 includes the multiple gas supply sources 51, the gas supply unit 50 may be configured to switch the processing gas to be supplied to a different processing gas or may be configured to supply a mixed gas of a plurality of processing gases. However, the present disclosure is not limited thereto. The plasma processing apparatus 10 includes an antenna 62 for plasma generation that is disposed on or above the chamber 11 (the dielectric window 61). The antenna 62 has at least one coil. In the example of FIG. 1, the antenna 62 has an outer coil 621 and an inner coil 622. The inner coil 622 is disposed to surround the gas injection unit 41. The outer coil 621 is disposed to surround the inner coil 622.

At least one of the outer coil 621 and the inner coil 622 functions as a primary coil connected to a RF power supply 71. Therefore, the RF power supply 71 is configured to supply a RF source power to at least one of the outer coil 621 and the inner coil 622. A frequency of the RF source power is higher than that of the RF bias power. One of the outer coil 621 and the inner coil 622 that is not connected to the RF power supply 71 functions as a secondary coil that is inductively coupled to the primary coil. The RF power supply 71 is an example of a power supply unit. The frequency and the power of the RF source power are controlled by the controller 100 to be described later. The outer coil 621 and the inner coil 622 may be arranged at the same height or different heights. In the example of FIG. 1, the inner coil 622 is disposed at a position lower than that of the outer coil 621.

The plasma processing apparatus 10 includes the controller 100 for controlling the individual components of the plasma processing apparatus 10. The controller 100 includes a memory such as a read only memory (ROM) or a random access memory (RAM), and a processor such as a central processing unit (CPU). The memory in the controller 100 stores programs or data such as recipes. The processor in the controller 100 reads out and executes the programs stored in the memory in the controller 100. The processor controls the individual components of the plasma processing apparatus 10 based on the data such as the recipes stored in the memory in the controller 100.

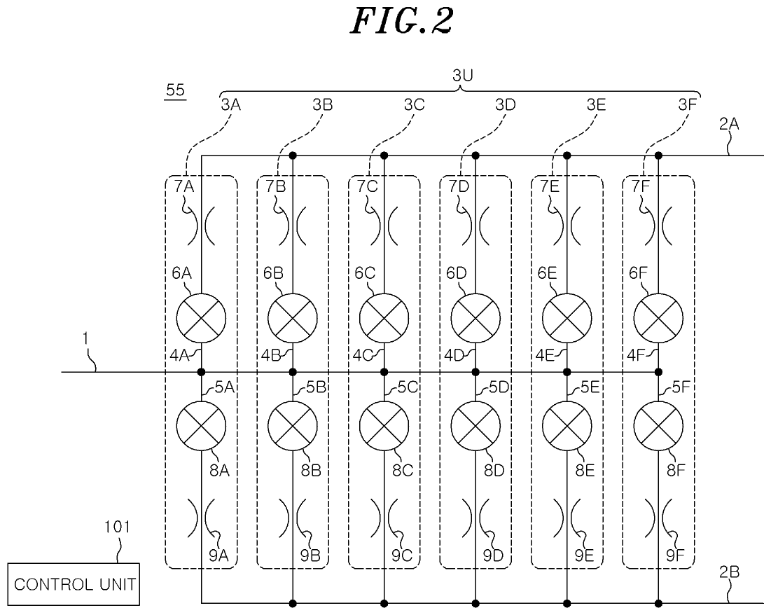

Next, the gas splitter 55 will be further described with reference to FIG. 2. FIG. 2 shows an example of a configuration of the gas splitter 55.

The gas splitter 55 includes a primary supply line 1, secondary supply lines 2A and 2B, a flow adjusting unit 3U including a plurality of flow adjusting lines 3A to 3F, and a control unit 101.

The primary supply line 1 is connected to the gas supply unit 50 through the gas supply line 54. The secondary supply line 2A is connected to the inlet port 42a through the gas supply line 56a. The secondary supply line 2B is connected to the inlet port 42b through the gas supply line 56b.

The flow adjusting unit 3U includes the flow adjusting lines 3A to 3F. In the example shown in FIG. 2, the flow adjusting lines 3A to 3F are arranged in that order from an upstream side.

One flow adjusting line has a pair of lines. In the example shown in FIG. 2, the flow adjusting line 3A has a pair of lines 4A and 5A. In other words, the flow adjusting line 3A has a pair of a first line 4A and a second line 5A.

The first line 4A has one end connected to the primary supply line 1 and the other end connected to the secondary supply line 2A. In other words, the first line 4A is a flow channel that connects the gas supply unit 50 and the inlet port 42a. A first valve 6A and a first orifice 7A are disposed on the first line 4A in that order from the upstream side. In other words, the first orifice 7A is disposed downstream of the first valve 6A. The second line 5A has one end connected to the primary supply line 1 and the other end connected to the secondary supply line 2B. In other words, the second line 5A is a flow channel that connects the gas supply unit 50 and the inlet port 42b. A second valve 8A and a second orifice 9A are disposed on the second line 5A in that order from the upstream side. In other words, the second orifice 9A is disposed downstream of the second valve 8A. The valves 6A and 8A are, for example, electromagnetic valves, and an opening/closing of the valve 6A and the valve 8A is controlled by the control unit 101. The first orifice 7A and the second orifice 9A have the same size. In other words, an opening area of the first orifice 7A is the same as that of the second orifice 9A. That is to say, an orifice diameter of the first orifice 7A is the same as that of the second orifice 9A.

Similarly, the flow adjusting line 3B has a pair of lines 4B and 5B. In other words, the flow adjusting line 3B has a pair of a first line 4B and a second line 5B. The first line 4B has a first valve 6B and a first orifice 7B. The second line 5B has a second valve 8B and a second orifice 9B. The first orifice 7B and the second orifice 9B have the same size.

Similarly, the flow adjusting line 3C has a pair of lines 4C and 5C. In other words, the flow adjusting line 3C has a pair of a first line 4C and a second line 5C. The first line 4C has a first valve 6C and a first orifice 7C. The second line 5C has a second valve 8C and a second orifice 9C. The first orifice 7C and the second orifice 9C have the same size.

Similarly, the flow adjusting line 3D has a pair of lines 4D and 5D. In other words, the flow adjusting line 3D has a pair of a first line 4D and a second line 5D. The first line 4D has a first valve 6D and a first orifice 7D. The second line 5D has a second valve 8D and a second orifice 9D. The first orifice 7D and the second orifice 9D have the same size.

Similarly, the flow adjusting line 3E has a pair of lines 4E and 5E. In other words, the flow adjusting line 3E has a pair of a first line 4E and a second line 5E. The first line 4E has a first valve 6E and a first orifice 7E. The second line 5E has a second valve 8E and a second orifice 9E. The first orifice 7E and the second orifice 9E have the same size.

Similarly, the flow adjusting line 3F has a pair of lines 4F and 5F. In other words, the flow adjusting line 3F has a pair of a first line 4F and a second line 5F. The first line 4F has a first valve 6F and a first orifice 7F. The second line 5F has a second valve 8F and a second orifice 9F. The first orifice 7F and the second orifice 9F have the same size.

The orifices 7A to 7F (9A to 9F) of the flow adjusting lines 3A to 3F may have different sizes, or at least some of the orifices 7A to 7F (9A to 9F) may have the same size. In the following description, it is assumed that the orifices 7A to 7F (9A to 9F) of the flow adjusting lines 3A to 3F have different sizes and the sizes of the orifices become smaller from the flow adjusting line 3A of the upstream side toward the flow adjusting line 3F of the downstream side.

The controller 100 transmits data about a flow ratio to the control unit 101 based on, for example, a processing recipe in the plasma processing apparatus 10, and the controller 100 instructs the flow ratio. The control unit 101 controls, on receipt of the data about the flow ratio, an opening/closing of each of the first valves 6A to 6F and the second valves 8A to 8F in the flow adjusting lines 3A to 3F based on the flow ratio. Although the control unit 101 is disposed in the gas splitter 55 in FIG. 2, the present disclosure is not limited thereto and the control unit 101 may be installed as one function of the controller 100.

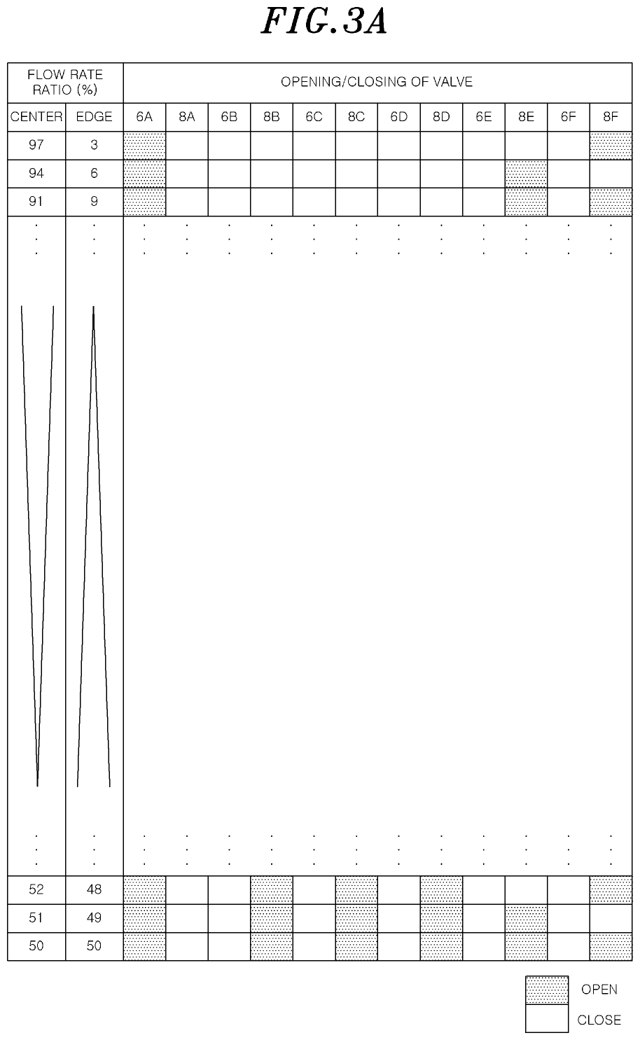

FIGS. 3A and 3B show examples of a table stored in a storage unit of the control unit 101. In the tables shown in FIGS. 3A and 3B, “Center” indicates a flow rate of the injection port 43a, i.e., a flow rate of the gas supplied to the inlet port 42a, i.e., a flow rate of the secondary supply line 2A. “Edge” indicates a flow rate of the injection port 43b, i.e., a flow rate of the gas supplied to the inlet port 42b, i.e., a flow rate of the secondary supply line 2B. Each of the tables has a plurality of records, and each record has a flow ratio and a combination of the opening/closing of the valves 6A to 6F and 8A to 8F corresponding to the flow ratio. Further, in the tables shown in FIGS. 3A and 3B, the opening of the valve is indicated by lattice hatching, and the closing of the valve is indicated by white.

FIG. 3A shows an example of a table used when the flow rate of “Center” is higher than or equal to the flow rate of “Edge” (Center/Edge≥1). It is assumed that the table shown in FIG. 3A has an n-number of records. In FIG. 3A, a first record has a first flow ratio (Center:Edge=97:3) and a first valve opening/closing pattern corresponding to the first flow ratio. In the first valve opening/closing pattern, the valves 6A and 8F are opened and the valves 6B to 6F and 8A to 8E are closed. A second record has a second flow ratio (Center:Edge=94:6) and a second valve opening/closing pattern corresponding to the second flow ratio. In the second valve opening/closing pattern, the valves 6A and 8E are opened and the valves 6B to 6F, 8A to 8D, and 8F are closed. A third record has a third flow ratio (Center:Edge=91:9) and a third valve opening/closing pattern corresponding to the third flow ratio. In the third valve opening/closing pattern, the valves 6A, 8E, and 8F are opened and the valves 6B to 6F and 8A to 8D are closed. An (n-2)th record has an (n-2)th flow ratio (Center:Edge=52:48) and an (n-2)th valve opening/closing pattern corresponding to the (n-2)th flow ratio. In the (n-2)th valve opening/closing pattern, the valves 6A, 8B to 8D and 8F are opened and the valves 6B to 6F, 8A and 8E are closed. An (n-1)th record has an (n-1)th flow ratio (Center:Edge=51:49) and an (n-1)th valve opening/closing pattern corresponding to the (n-1)th flow ratio. In the (n-1)th valve opening/closing pattern, the valves 6A and 8B to 8E are opened and the valves 6B to 6F, 8A, and 8F are closed. An n-th record has an n-th flow ratio (Center:Edge=50:50) and an n-th valve opening/closing pattern corresponding to the n-th flow ratio. In the n-th valve opening/closing pattern, the valves 6A and 8B to 8F are opened and the valves 6B to 6F and 8A are closed.

FIG. 3B shows an example of a table used when the flow rate of Edge is higher than the flow rate of Center (Center/Edge<1). It is assumed that the table shown in FIG. 3B has an n-number of records. In FIG. 3B, a first record has a first flow ratio (Center:Edge=3:97) and a first valve opening/closing pattern corresponding to the first flow ratio. In the first valve opening/closing pattern, the valves 6F and 8A are opened and the valves 6A to 6E and 8B to 8F are closed. A second record has a second flow ratio (Center:Edge=6:94) and a second valve opening/closing pattern corresponding to the second flow ratio. In the second valve opening/closing pattern, the valves 6E and 8A are opened and the valves 6A to 6D, 6F and 8B to 8F are closed. A third record has a third flow ratio (Center:Edge=9:91) and a third valve opening/closing pattern corresponding to the third flow ratio. In the third valve opening/closing pattern, the valves 6E, 6F, and 8A are opened and the valves 6A to 6D and 8B to 8F are closed. An (n-1)th record has an (n-1)th flow ratio (Center:Edge=48:52) and an (n-1)th valve opening/closing pattern corresponding to the (n-1)th flow ratio. In the (n-1)th valve opening/closing pattern, the valves 6B to 6D, 6F and 8A are opened and the valves 6A, 6E and 8B to 8F are closed. An n-th record has an n-th flow ratio (Center:Edge=49:51) and an n-th valve opening/closing pattern corresponding to the n-th flow ratio. In the n-th valve opening/closing pattern, the valves 6B to 6E and 8A are opened and the valves 6A, 6F and 8B to 8F are closed.

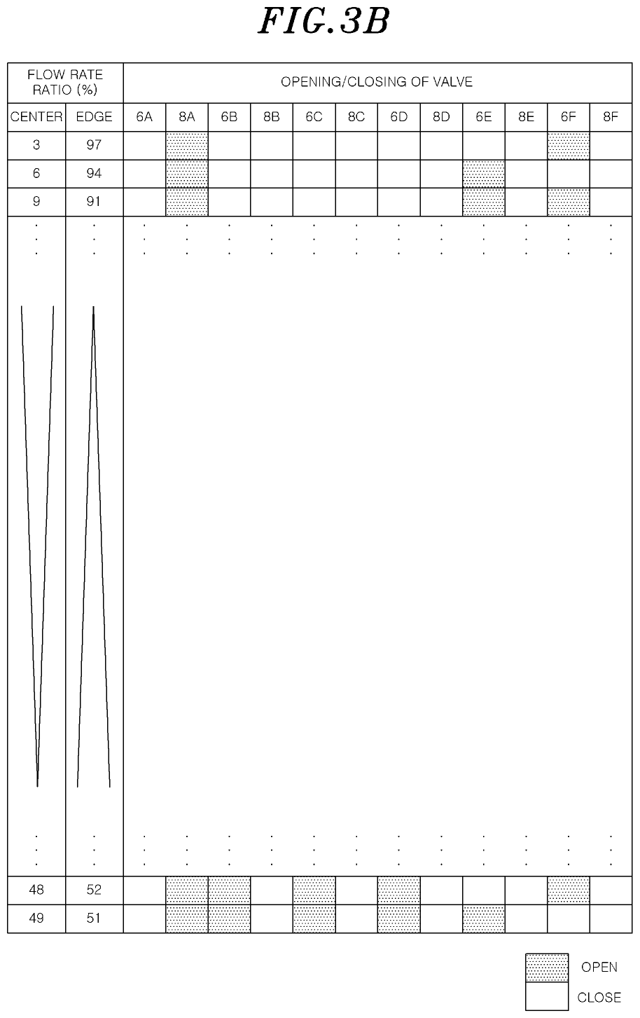

FIG. 4 is a flowchart for explaining a process of a flow ratio control by the control unit 101.

In step S101, the control unit 101 receives data about a flow ratio from, for example, the controller 100.

In step S102, the control unit 101 selects an instructed flow ratio (flow ratio included in the received data) and one of a plurality of records in the tables (see FIGS. 3A and 3B) stored in the control unit 101. In the case of using the tables of FIGS. 3A and 3B, when the flow rate of “Center” is higher than or equal to the flow rate of “Edge” (Center/Edge≥1), a record is selected from the table of FIG. 3A. On the other hand, when the flow rate of “Center” is less than the flow rate of “Edge” (Center/Edge<1), a record is selected from the table of FIG. 3B. Accordingly, the combination of the opening/closing (valve opening/closing pattern) of the valves 6A to 6F and 8A to 8F corresponding to the instructed flow ratio is determined. Specifically, the control unit 101 refers to the table shown in FIGS. 3A and 3B to select the record corresponding to the instructed flow ratio and acquire the combination of the opening/closing of the valves corresponding to the selected record. For example, when the flow ratio is instructed to be “Center:Edge=91:9”, the control unit 101 selects the third record corresponding to the instructed flow ratio from the table shown in FIG. 3A. Then, the control unit 101 acquires the third valve opening/closing pattern (the valves 6A, 8E, and 8F are opened and the valves 6B to 6F and 8A to 8D are closed) included in the selected third record so as to determine the combination of the opening/closing of the valves 6A to 6F and 8A to 8F.

In step S103, the control unit 101 controls the opening/closing of the valves 6A to 6F and 8A to 8F based on the combination of the opening/closing of the valves determined in step S102. Here, the control unit 101 controls the valves to be opened in the order from the valves 6A and 8A of the flow adjusting line 3A distant from the chamber 11 toward the valves 6F and 8F of the flow adjusting line 3F close to the chamber 11. In other words, the control unit 101 controls the valves to be opened in the order from the valves 6A and 8A of the upstream flow adjusting line 3A toward the valves of the downstream flow adjusting lines.

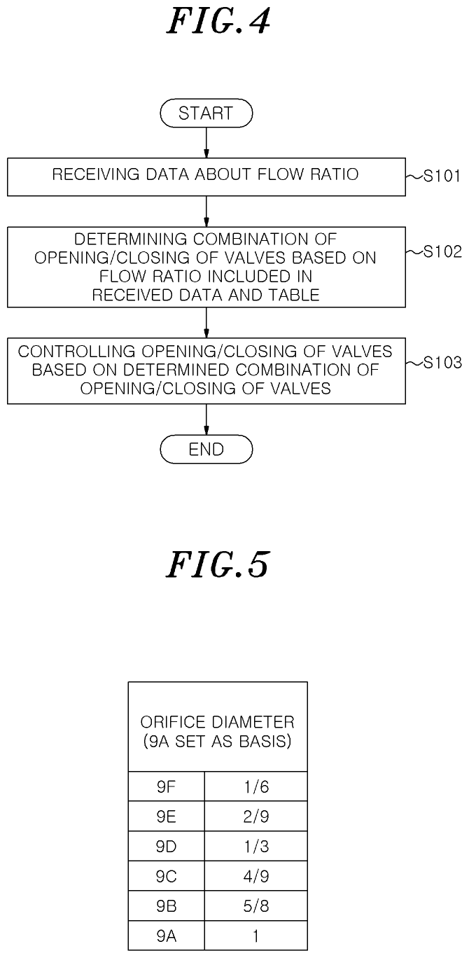

FIG. 5 shows an example of a combination of sizes of the orifices 9A to 9F (7A to 7F). When the orifice diameter D of the orifice 9A (7A) of the first flow adjusting line 3A is set to “1,” the orifice diameter D of the orifice 9B (7B) of the second flow adjusting line 3B is “5/8”; the orifice diameter D of the orifice 9C (7C) of the third flow adjusting line 3C is “4/9”; the orifice diameter D of the orifice 9D (7D) of the fourth flow adjusting line 3D is “1/3”; the orifice diameter D of the orifice 9E (7E) of the fifth flow adjusting line 3E is “2/9”; and the orifice diameter D of the orifice 9F (7F) of the sixth flow adjusting line 3F is “1/6.”

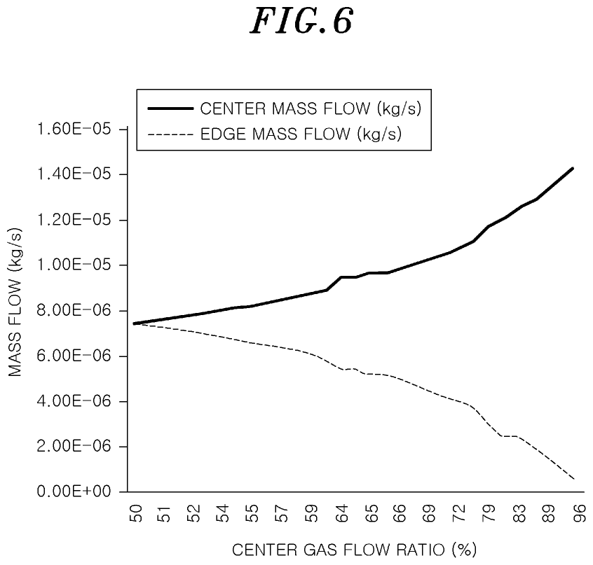

FIG. 6 is an example of a graph showing a simulation result in the case of controlling a flow rate based on the combination of the orifice diameters shown in FIG. 5 and the tables shown in FIGS. 3A and 3B. The horizontal axis represents a flow ratio of a gas on the center side (center side gas flow/total flow), and the vertical axis represents a simulation result of a flow rate. The flow rate of the gas on the center side is indicated by a solid line in the graph, and the flow rate of the gas on the edge side is indicated by a dashed line in the graph.

As can be seen from FIG. 6, the flow ratio can be desirably controlled by controlling the opening/closing of the valves 6A to 6F and 8A to 8F.

As described above, in accordance with the plasma processing apparatus 10 of the present embodiment, the flow ratio of the processing gas supplied into the chamber 11 from the injection ports 43a and 43b can be changed depending on the processing recipe.

Further, the gas splitter 55 is configured to change the flow ratio by controlling the opening/closing of the valves 6A to 6F and 8A to 8F. Further, the control unit 101 can determine the opening/closing of the valves 6A to 6F and 8A to 8F based on the tables stored in advance therein (see FIGS. 3A and 3B). Therefore, the switching response speed can be improved compared to the case of controlling a flow rate using, e.g., a thermal mass flow meter.

Further, in step S103, in the case of controlling the opening/closing of the valves 6A to 6F and 8A to 8F, the opening/closing of the valves of the upstream flow adjusting line among the valves 6A to 6F and 8A to 8F of the flow adjusting lines 3A to 3F is controlled first. In other words, in the case of opening the first valves 6A to 6F, the control unit 101 controls the first valves 6A to 6F to be opened in the order from a valve most distant from the chamber 11. Further, in the case of opening the second valves 8A to 8F, the control unit 101 controls the second valves 8A to 8F in the order from a valve most distant from the chamber 11. Since the flow channel lengths from the respective flow adjusting lines 3 to the inlet ports 42a and 42b of the chamber 11 are different from one another, the time period required from the opening/closing of each of the valves 6A to 6F and 8A to 8F until the gas reaches the inlet ports 42a and 42b is different from the time period for the other valves 6A to 6F and 8A to 8F. By controlling the opening/closing of the valves 6A to 6F and 8A to 8F in consideration of the difference in the flow channel lengths from the respective flow adjusting lines 3 to the inlet ports 42a and 42b, it is possible to reduce the time period required to stabilize the flow rate after the switching of the flow ratio. Further, it is possible to suppress an increase in the difference between a target flow rate and the actual flow rate during a period between the switching of the flow ratio and the stabilization of the flow rate. Accordingly, a sudden increase or decrease in the flow rate can be suppressed.

Further, as shown in FIG. 2, the valves 6A to 6F and 8A to 8F are preferably disposed respectively upstream of the orifices 7A to 7F and 9A to 9F. Here, the pressure upstream of the orifice is set to P1, and the pressure downstream of the orifice is set to P2.

Since the valves 6A to 6F and 8A to 8F are disposed respectively upstream of the orifices 7A to 7F and 9A to 9F, the pressure difference between the upstream side and the downstream side of the orifice can be increased (specifically, P1>2P2). Accordingly, the flow ratio can be controlled by a ratio of a flow channel cross-sectional area A of the orifice.

While the embodiments of the plasma processing apparatus 10 have been described, the present disclosure is not limited by the above-described embodiments, and various changes and modifications can be made without departing from the scope of the appended claims and the gist thereof.

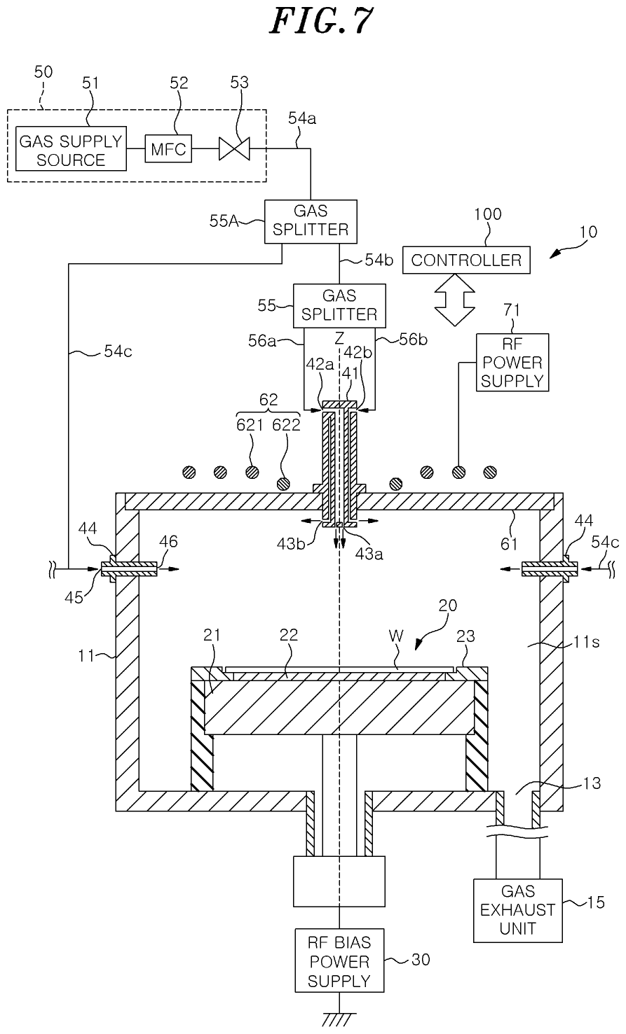

FIG. 7 is a schematic cross-sectional view showing another example of the plasma processing apparatus 10. The plasma processing apparatus 10 shown in FIG. 7 includes a gas injection unit (side gas injector) 44 on the sidewall of the chamber 11. The gas injection unit 44 includes a plurality of inlet ports 45 and a plurality of injection ports 46. Further, the gas supply unit 50 is configured to supply a processing gas to a gas splitter 55A through a gas supply line 54a. The gas splitter 55A controls a flow ratio and splits the processing gas to a gas supply line 54b and a gas supply line 54c. The gas supply line 54b is connected to the gas splitter 55. The gas supply line 54c is connected to the gas injection unit 44.

The gas splitter 55 is configured to switch the flow ratio of the inlet port 42a (example of the first gas inlet) to the inlet port 42b (example of the second gas inlet). The gas splitter 55A is configured to switch the flow ratio of the inlet ports 42a and 42b (example of the first gas inlet) to the inlet port 45 (example of the second gas inlet). The configuration of the gas splitter 55A is the same as that of the gas splitter 55 shown in FIG. 2, so that redundant description thereof will be omitted. By controlling the gas splitters 55 and 55A, the flow ratio of the gas injected into the chamber 11 from each of the injection ports 43a, 43b, and 46 can be controlled.

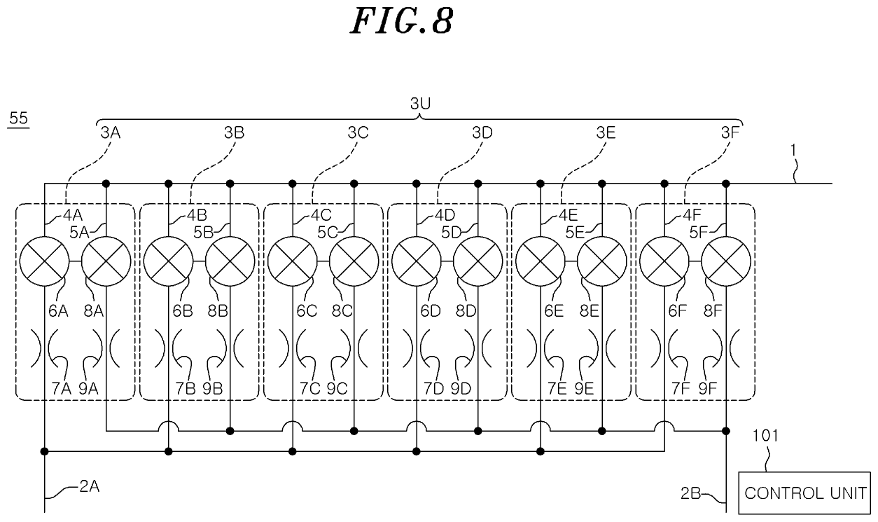

FIG. 8 shows a schematic configuration of another example of the gas splitter 55. In the gas splitter 55 shown in FIG. 2, a branch position from the primary supply line 1 to the first line 4A (4B to 4F) and a branch position from the primary supply line 1 to the second line 5A (5B to 5F) are the same. However, the present disclosure is not limited thereto. As shown in FIG. 8, a branch position from the primary supply line 1 to the first line 4A (4B to 4F) and a branch position from the primary supply line 1 to the second line 5A (5B to 5F) may be different. Moreover, the flow channel lengths may be different.

Further, in the gas splitter 55 shown in FIG. 2, the relationship between an upstream line and a downstream line of the flow adjusting lines 3A to 3F in the primary supply line 1 (the flow adjusting line 3A is the upstream line and the flow adjusting line 3F is the downstream line) is the same as the relationship between an upstream line and a downstream line of the flow adjusting lines 3A to 3F in the secondary supply lines 2A and 2B (the flow adjusting line 3A is the upstream line and the flow adjusting line 3F is the downstream line). However, the present disclosure is not limited thereto. As shown in FIG. 8, the relationship between an upstream line and a downstream line of the flow adjusting lines 3A to 3F in the primary supply line 1 (the flow adjusting line 3F is the upstream line and the flow adjusting line 3A is the downstream line) and the relationship between an upstream line and a downstream line of the flow adjusting lines 3A to 3F in the secondary supply line 2B (the flow adjusting line 3A is the upstream line and the flow adjusting lien 3F is the downstream line) may be different. Further, the relationship between an upstream line and a downstream line of the flow adjusting lines 3A to 3F in the secondary supply line 2A (the flow adjusting line 3F is the upstream line and the flow adjusting line 3A is the downstream line) and the relationship between an upstream line and a downstream line of the flow adjusting lines 3A to 3F in the secondary supply line 2B (the flow adjusting line 3A is the upstream line and the flow adjusting line 3F is the downstream line) may be different. The configuration shown in FIG. 2 is preferable because the flow channel lengths from the gas supply unit 50 to the inlet ports 42a and 42b can be the same.

Further, the number of the flow adjusting lines 3A to 3F included in the flow adjusting unit 3U is not limited to six, and may be seven or more. By increasing the number of flow adjusting lines 3, the resolution of the flow ratio control can be improved.

The plasma processing apparatus according to the embodiments of the present disclosure are considered in all respects to be illustrative and not restrictive. The above-described embodiments may be variously changed and modified without departing from the scope of the appended claims and the gist thereof. The above-described embodiments may include other configurations without contradicting each other and may be combined without contradicting each other. The plasma processing apparatus of the embodiments of the present disclosure can be applied to any type of apparatus using atomic layer deposition (ALD), capacitively coupled plasma (CCP), inductively coupled plasma (ICP), a radial line slot antenna (RLSA), electron cyclotron resonance (ECR) plasma, and helicon wave plasma (HWP). The plasma processing apparatus may be any apparatus that performs plasma processing such as film formation or etching on a substrate. Therefore, the plasma processing apparatus of the embodiments of the present disclosure can be applied to an apparatus including a chamber having a plasma processing space, a substrate support disposed in the plasma processing space, and a plasma generation unit configured to generate plasma from a gas supplied to the plasma processing space.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made departing from the spirit of the disclosures. The accompanying claims and their equivalents are intended to cover such forms or modifications as would fall within the scope and spirit of the disclosures.

1. A gas supply system connected between at least one gas source and a chamber having a first gas inlet and a second gas inlet, comprising:
a flow adjusting unit including a plurality of flow adjusting lines, each including a pair of a first line and a second line, the first line connecting the at least one gas source and the first gas inlet and including a first valve and a first orifice, the second line connecting the at least one gas source and the second gas inlet and including a second valve and a second orifice, the first orifice and the second orifice in each of the flow adjusting lines have the same size; and
at least one control unit configured to control an opening/closing of the first valve and an opening/closing of the second valve in each of the flow adjusting lines.

2. The gas supply system of claim 1, wherein a size of an orifice of one of the flow adjusting lines is different from a size of an orifice of another one of the flow adjusting lines.

3. The gas supply system of claim 2, wherein the flow adjusting lines include first to sixth flow adjusting lines,
diameters of a first orifice and a second orifice in the second flow adjusting line are 5/8 of diameters of a first orifice and a second orifice in the first flow adjusting line,
diameters of a first orifice and a second orifice in the third flow adjusting line are 4/9 of the diameters of the first orifice and the second orifice in the first flow adjusting line,
diameters of a first orifice and a second orifice in the fourth flow adjusting line are 1/3 of the diameters of the first orifice and the second orifice in the first flow adjusting line,
diameters of a first orifice and a second orifice in the fifth flow adjusting line are 2/9 of the diameters of the first orifice and the second orifice in the first flow adjusting line, and
diameters of a first orifice and a second orifice in the sixth flow adjusting line are 1/6 of the diameters of the first orifice and the second orifice in the first flow adjusting line.

4. The gas supply system of claim 3, wherein the at least one control unit has a table in which a flow ratio through which a gas supplied from the at least one gas source is supplied to the first gas inlet and the second gas inlet based thereon is associated with the opening/closing of the first valve and the opening/closing of the second valve in each of the flow adjusting lines, and
the at least one control unit is configured to control the opening/closing of the first valve and the opening/closing of the second valve in each of the flow adjusting lines based on received data about the flow ratio and the table.

5. The gas supply system of claim 4, wherein the at least one control unit is configured to control the flow adjusting unit to open a plurality of first valves among the entire first valves of the flow adjusting lines and/or to open a plurality of second valves among the entire second valves of the flow adjusting lines.

6. The gas supply system of claim 5, wherein the at least one control unit controls the flow adjusting unit to open the plurality of first valves among the entire first valves of the flow adjusting lines in the order from one of the plurality of first valves most distant from the chamber, and
controls the flow adjusting unit to open the plurality of second valves among the entire second valves of the flow adjusting lines in the order from one of the plurality of second valves most distant from the chamber.

7. The gas supply system of claim 6, wherein in each of the flow adjusting lines,
the first valve is disposed upstream of the first orifice in the first line, and
the second valve is disposed upstream of the second orifice in the second line.

8. The gas supply system of claim 1, wherein the at least one control unit has a table in which a flow ratio through which a gas supplied from the at least one gas source is supplied to the first gas inlet and the second gas inlet based thereon is associated with the opening/closing of the first valve and the opening/closing of the second valve in each of the flow adjusting lines, and
the at least one control unit is configured to control the opening/closing of the first valve and the opening/closing of the second valve in each of the flow adjusting lines based on received data about the flow ratio and the table.

9. The gas supply system of claim 1, wherein the at least one control unit is configured to control the flow adjusting unit to open a plurality of first valves among the entire first valves of the flow adjusting lines and/or to open a plurality of second valves among the entire second valves of the flow adjusting lines.

10. The gas supply system of claim 1, wherein the at least one control unit is configured to control the flow adjusting unit to open a plurality of first valves among the entire first valves of the flow adjusting lines in the order from one of the plurality of first valves most distant from the chamber, and
to control the flow adjusting unit to open a plurality of second valves among the entire second valves of the flow adjusting lines in the order from one of the plurality of second valves most distant from the chamber.

11. The gas supply system of claim 1, wherein in each of the flow adjusting lines,
the first valve is disposed upstream of the first orifice in the first line, and
the second valve is disposed upstream of the second orifice in the second line.

12. A plasma processing apparatus comprising:
a chamber having a first gas inlet and a second gas inlet and a plasma processing space in fluid communication with the first gas inlet and the second gas inlet; and
the gas supply system described in claim 1.

13. A control method of a gas supply system connected between at least one gas source and a chamber having a first gas inlet and a second gas inlet, the gas supply system including: a flow adjusting unit including a plurality of flow adjusting lines, each including a pair of a first line and a second line, the first line connecting the at least one gas source and the first gas inlet and having a first valve and a first orifice; the second line connecting the at least one gas source and the second gas inlet and having a second valve and a second orifice; and the first orifice and the second orifice in each of the flow adjusting lines having the same size; and a storage unit configured to store a table in which a flow ratio through which a gas supplied from the at least one gas source is supplied to the first gas inlet and the second gas inlet based thereon is associated with an opening/closing of the first valve and an opening/closing of the second valve in each of the flow adjusting lines,
the control method comprising:
receiving data about the flow ratio;
determining whether to open or close the first valve and the second valve in each of the flow adjusting lines based on the received data and the table; and
controlling the opening/closing of the first valve and the opening/closing of the second valve in each of the flow adjusting lines based on the determination result.

14. The control method of claim 13, wherein the controlling of the opening/closing of the first valve and the opening/closing of the second valve includes:
opening a plurality of first valves among the entire first valves of the flow adjusting lines in the order from one of the plurality of first valves most distant from the chamber; and
opening a plurality of second valves among the entire second valves of the flow adjusting lines in the order from one of the plurality of second valves most distant from the chamber.
